(19) United States
(12) Patent Application Publication
(10) Pub. No.: US 2022/0102624 A1
(43) Pub. Date: Mar. 31, 2022

(54) ION BEAM ETCHING WITH GAS TREATMENT AND PULSING

(71) Applicant: Lam Research Corporation, Fremont, CA (US)

(72) Inventors: Seokmin YUN, Dublin, CA (US); Zhimin WAN, Milpitas, CA (US); Shuogang HUANG, San Jose, CA (US); Weiyi LI, San Jose, CA (US); Gowri Channa KAMARTHY, Pleasanton, CA (US)

(21) Appl. No.: 17/310,318

(22) PCT Filed: Jan. 29, 2020
(86) PCT No.: PCT/US2020/015587

§ 371 Date: Jul. 27, 2021

Related U.S. Application Data
(60) Provisional application No. 62/800,058, filed on Feb. 1, 2019.

(51) Int. Cl. H01L 43/12; H01J 37/305; H01J 37/08; H01L 27/22

(52) U.S. Cl. CPC H01L 43/12; H01J 37/3053; H01J 2237/006; H01L 27/222; H01J 2237/3174; H01J 37/08

(57) ABSTRACT

One or more layers of a magnetic random access memory (MRAM) stack on a substrate are etched by ion beam etching. An ion beam of an inert gas is generated in an ion beam source chamber and applied to a substrate in a continuous or pulsed manner. Without passing through the ion beam source chamber, a reactive gas is flowed directly into a processing chamber in which the substrate is located, where the reactive gas is pulsed or continuously provided into the processing chamber. The reactive gas may include a carbon-containing gas having a hydroxyl group that is flowed towards the substrate to limit re-deposition of sputtered atoms on exposed surfaces of the substrate from ion beam etching.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Magnetic random access memory (MRAM) is a non-volatile memory utilizing a magnetoresistive effect such as tunneling magnetoresistance (TMR). MRAM has as high of an integration density as dynamic random access memory (DRAM) and as much high-speed performance as static random access memory (SRAM). Because MRAM stack materials are highly non-volatile, ion beam etching techniques are typically employed to etch MRAM stacks.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of ion beam etching a substrate. The method includes generating an ion beam of an inert gas from an ion beam source chamber, applying the ion beam of the inert gas to a substrate in a processing chamber outside the ion beam source chamber, where the ion beam etches one or more layers of a magnetic random access memory (MRAM) stack on the substrate, and introducing a reactive gas directly into the processing chamber and towards the substrate.

In some implementations, the reactive gas includes a carbon-containing gas having a hydroxyl group. In some implementations, the carbon-containing gas is selected from a group consisting of: an alcohol, a carboxylic acid, an organic hydroperoxide, a hemiacetal, and a hemiketal. In some implementations, the carbon-containing gas includes methanol. In some implementations, the reactive gas includes a fluorine-containing gas or a nitrogen-containing gas. In some implementations, the MRAM stack includes an MTJ stack, where the MTJ stack includes a top magnetic layer, a bottom magnetic layer, and a tunnel barrier layer between the top magnetic layer and the bottom magnetic layer. In some implementations, sidewalls of the MRAM stack after etching the one or more layers and after introducing the reactive gas are substantially free of re-deposited etched byproducts. In some implementations, applying the ion beam comprises applying the ion beam continuously to etch the one or more layers of the MRAM stack. In some implementations, applying the ion beam comprises pulsing the ion beam to etch the one or more layers of the MRAM stack.

Another aspect involves a method of ion beam etching a substrate. The method includes generating an ion beam of an inert gas in an ion beam source chamber, and pulsing the ion beam of the inert gas to a substrate in a processing chamber outside the ion beam source chamber, wherein the ion beam etches one or more layers of a magnetic random access memory (MRAM) stack on the substrate.

In some implementations, an amplitude of the ion beam is modulated over time when pulsing the ion beam. In some implementations, the method further includes introducing a reactive gas directly into the processing chamber towards the substrate. In some implementations, the reactive gas includes a carbon-containing gas having a hydroxyl group, wherein the carbon-containing gas is selected from a group consisting of: an alcohol, a carboxylic acid, an organic hydroperoxide, a hemiacetal, and a hemiketal. In some implementations, the reactive gas is flowed continuously. In some implementations, the reactive gas is pulsed. In some implementations, the ion beam of the inert gas and the reactive gas are alternatingly pulsed into the processing chamber.

Another aspect involves an apparatus for performing ion beam etching of a substrate. The apparatus includes an ion beam source chamber, a processing chamber coupled to the ion beam source chamber, where the processing chamber is configured to support a substrate located therein, where a magnetic random access memory (MRAM) stack includes one or more layers disposed on the substrate, a gas delivery system coupled to the processing chamber, and a controller. The controller is configured to provide instructions to perform the following operations: generate an ion beam of an inert gas in the ion beam source chamber, apply the ion beam of the inert gas to the substrate in the processing chamber, where the ion beam etches the one or more layers of the MRAM stack on the substrate, and introduce a reactive gas through the gas delivery system and directly into the processing chamber towards the substrate.

In some implementations, the ion beam is pulsed and the reactive gas is flowed continuously. In some implementations, the ion beam is continuous and the reactive gas is pulsed. In some implementations, the ion beam is pulsed and the reactive gas is pulsed. In some implementations, the ion beam and the reactive gas are alternatingly pulsed into the processing chamber.

### BRIEF DESCRIPTION OF THE DRAWINGS

FIG. 1 is a cross-sectional schematic illustration of an example MRAM stack on a substrate according to some implementations.

FIG. 2 is a cross-sectional schematic illustration of MRAM stacks undergoing ion beam etching and sidewall re-deposition.

FIG. 3 is a schematic diagram of an example ion beam etching apparatus according to some implementations.

FIG. 4 shows a flow diagram of an example method of ion beam etching a substrate according to some implementations.

FIGS. 5A-5B show cross-sectional schematic illustrations of carbon-containing gas passivating sidewalls and exposed surfaces of MRAM stacks to limit sidewall re-deposition.

FIG. 6A shows a timing diagram of applying an ion beam in pulses simultaneous with flowing continuously reactive gas according to some implementations.

FIG. 6B shows a timing diagram of applying an ion beam continuously simultaneous with pulsing reactive gas according to some implementations.

FIG. 6C shows a timing diagram of applying an ion beam in pulses that alternates with pulsing reactive gas according to some implementations.

FIG. 7A shows a timing diagram of flowing reactive gas at an initial processing time interval when performing ion beam etching according to some implementations.

FIG. 7B shows a timing diagram of flowing reactive gas at an ending processing time interval when performing ion beam etching according to some implementations.

FIG. 7C shows a timing diagram of flowing reactive gas at a middle processing time interval when performing ion beam etching according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction

Electronic devices use integrated circuits including memory to store data. One type of memory that is commonly used in electronic circuits is DRAM. DRAM stores each bit of data in separate capacitors of an integrated circuit. The capacitors can either be charged or discharged, representing two states of a bit. The electric charge of the capacitors slowly leaks off, so data is gradually lost unless capacitor charge is refreshed periodically. DRAM is a type of volatile memory, in contrast to non-volatile memory, since data is lost when power is removed.

Unlike conventional RAM chip technologies, data in MRAM is not stored as electric charge or current flows, but by magnetic storage elements. The magnetic storage elements may be formed from two ferromagnetic plates, each of which can hold a magnetization, separated by a thin non-magnetic insulating layer. One of the two ferromagnetic plates may be a permanent magnet set to a certain polarity, and the other one of the two ferromagnetic plates may be changed to match that of an external field to store memory. Such a configuration involving the two ferromagnetic plates and the thin non-magnetic insulating layer is known as a magnetic tunnel junction. MRAM is a type of non-volatile memory because it has the capability of holding saved data even if power is removed.

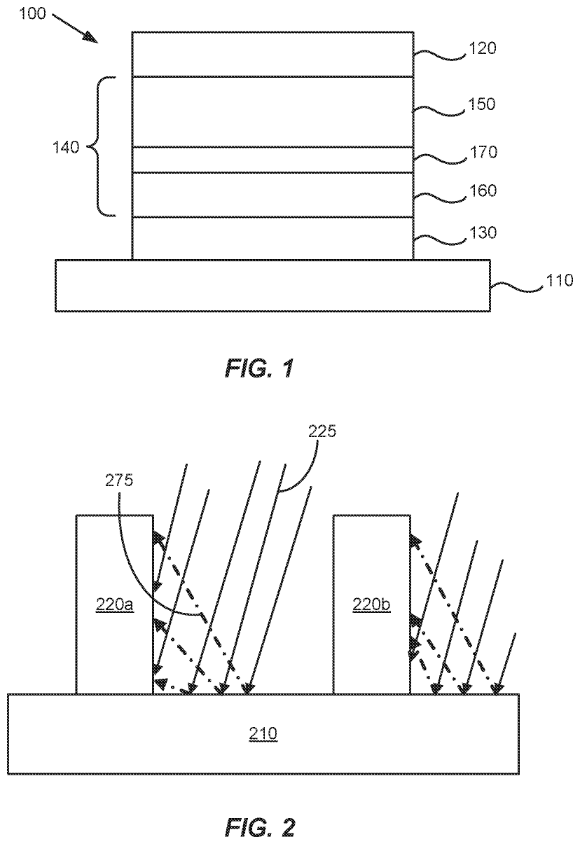

FIG. 1 is a cross-sectional schematic illustration of an example MRAM stack on a substrate according to some implementations. An MRAM stack 100 is disposed on a substrate 110 such as a silicon or glass substrate. The MRAM stack 100 can include a top electrode layer 120 and a bottom electrode layer 130. The bottom electrode layer 130 is disposed over the substrate 110 and can include a single layer metal or a multi-layer stack comprising a metal and other materials (e.g., dielectric materials). The top electrode layer 120 is disposed over the bottom electrode layer 130 and can include a single layer metal or a multi-layer stack comprising a metal and other materials (e.g., dielectric materials). The MRAM stack 100 may be arranged in an array of MRAM cells connected by metal word and bit lines. In some implementations, the bottom electrode layer 130 is connected to a word line and the top electrode layer 120 is connected to a bit line.

The MRAM stack 100 may include a memory element or magnetoresistive effect element, where the memory element or magnetoresistive effect element may be disposed between the top electrode layer 120 and the bottom electrode layer 130. The memory element or the magnetoresistive effect element may be a multi-layer film or magnetic tunnel junction (MTJ) stack 140. The MTJ stack 140 may include magnetic layers 150, 160 with a barrier layer 170 between the magnetic layers 150, 160. It will be understood that the MTJ stack 140 is illustrative and not restrictive, and can include many other layers not shown in FIG. 1. A first magnetic layer 150 is designed to serve as a free magnetic layer while a second magnetic layer 160 has a fixed magnetization direction. In some implementations, each of the first magnetic layer 150 and the second magnetic layer 160 includes a magnetic material such as cobalt (Co), nickel (Ni), iron (Fe), or combinations thereof (e.g., CoNi, CoFe, NiFe, CoNiFe). Each of the first magnetic layer 150 and the second magnetic layer 160 may further include a non-magnetic material such as boron (B), titanium (Ti), zirconium (Zr), hafnium (Hf), vanadium (V), niobium (Nb), tantalum (Ta), chromium (Cr), molybdenum (Mo), tungsten (W), aluminum (Al), silicon (Si), germanium (Ge), gallium (Ga), oxygen (O), nitrogen (N), carbon (C), platinum (Pt), palladium (Pd), ruthenium (Ru), or phosphorus (P) to form a magnetic compound (e.g., CoFeB). It will be appreciated that each of the first magnetic layer 150 and the second magnetic layer 160 may include one or more sub-layers. In some implementations, the second magnetic layer 160 may be coupled to and disposed over an anti-ferromagnetic layer (not shown). The MTJ stack 140 further includes a tunnel barrier layer or barrier layer 170 between the first magnetic layer 150 and the second magnetic layer 160, where the barrier layer 170 can include non-magnetic insulating material such as magnesium oxide (MgO). Thus, the MTJ stack 140 can include a pair of ferromagnetic layers (i.e., first magnetic layer 150 and second magnetic layer 160) with a non-magnetic intermediate layer (i.e., barrier layer 170) therebetween, which collectively produces a magnetoresistive effect. The resistivity of the MTJ stack 140 changes when the magnetization of the first magnetic layer 150 changes direction relative to that of the second magnetic layer 160, exhibiting a low resistance state when the magnetization orientation of the pair of ferromagnetic layers is substantially parallel and a high resistance state when the magnetization orientation of the pair of ferromagnetic layers is substantially anti-parallel. Therefore, the MRAM stack 100 can have two stable states to allow the MRAM stack 100 to serve as non-volatile memory.

In some implementations, the top electrode layer 120 can serve as a hard mask layer. During processing, the top electrode layer 120 can be deposited on the first magnetic layer 150 to pattern the underlying MTJ stack 140. It will be appreciated, however, that the position of the first magnetic layer 150 and the second magnetic layer 160 may be reversed so that the top electrode layer 120 is deposited on the second magnetic layer 160. In some implementations, the top electrode layer 120 includes tungsten (W), tantalum (Ta), tantalum nitride (TaN), titanium nitride (TiN), or other refractory metals. The MTJ stack 140 may be formed on the bottom electrode layer 130, where the bottom electrode layer 130 includes an electrically conductive material such as Ta, Ti, ruthenium (Ru), or the like.

It will be appreciated that the MRAM stack 100 may include several other layers not necessarily shown in FIG. 1. The layers in the MRAM stack 100 are not necessarily limited to metal or electrically conductive materials, but may include one or more layers of dielectric materials such as silicon dioxide (SiO₂).

Etching materials in MRAM stacks, including an MRAM stack 100 in FIG. 1, can present many challenges. Hard materials are commonly etched with a chemical etching process such as reactive ion etching (RIE). However, reactive ion etching of materials such as cobalt, iron, nickel, and other magnetic elements is difficult because such materials do not readily become volatile when exposed to typical etchant chemistries. Thus, many materials in MRAM stacks require more aggressive etchant chemistries. On the other hand, certain materials in MRAM stacks cannot tolerate such aggressive etchant chemistries. For example, a tunnel barrier layer such as MgO cannot tolerate reactive chemistries, where reactive chemistries can include radicals, ions, and neutral species containing fluorine, chlorine, iodine, oxygen, or hydrogen. These chemistries can cause a reaction with the tunnel barrier layer, thereby damaging the tunnel barrier layer and adversely impacting the electrical and magnetic properties of the MRAM stack. In some instances, the tunnel magnetoresistance (TMR) effect in the MRAM stack is compromised.

Ion beam etching (IBE) has been widely used in various industries for patterning thin films. Ion beam etching, which can also be referred to as ion milling, provides a highly-directional beam of charged particles to etch features on a substrate. Ion beam etching can be applied using inert gas for a purely physical etching process, though in some instances, ion beam etching can be applied using reactive species to increase material etching with a chemical/reactive component. Generally speaking, ion beam etching can physically etch through hard materials by using individual particles to ablate an exposed target to dislodge atoms and molecules. Ion beam etching can be used to etch materials in MRAM stacks while avoiding reactive chemistries that can otherwise degrade sensitive layers like the tunnel barrier layer.

Features in MRAM stacks can be patterned with ion beam etching. Ion beam etching is generally free of chemical reactions and will physically etch layers and materials exposed by a hard mask. This causes atoms and molecules to be sputtered from a target. The sputtered atoms and molecules may be directed towards exposed sidewalls of MRAM stacks and result in re-deposition on the exposed sidewalls. Accordingly, etching and re-deposition may occur simultaneously.

FIG. 2 is a cross-sectional schematic illustration of MRAM stacks undergoing ion beam etching and sidewall re-deposition. MRAM stacks 220a, 220b are formed on a substrate 210. Each of the MRAM stacks 220a, 220b may include a pair of magnetic layers, where a tunnel barrier layer (e.g., MgO) may be sandwiched between the magnetic layers. Examples of layers and materials in the MRAM stacks 220a, 220b are described above with respect to the MRAM stack 100 in FIG. 1. A conventional MRAM patterning process includes hard mask patterning, top electrode patterning, MTJ patterning, and bottom electrode patterning. It will be appreciated that ion beam etching may be used in some or all of the aforementioned patterning processes, where ion beam etching may be used in MTJ patterning. Reactive ion etching or ion beam etching may be used in top electrode patterning and bottom electrode patterning. To pattern the MRAM stacks 220a, 220b, an ion beam 225 may be applied to the substrate 210 to physically etch layers and materials exposed by a hard mask. The ion beam 225 causes atoms and molecules to be sputtered from surfaces exposed to the ion beam 225. As shown in FIG. 2, sputtered atoms and molecules 275 may be directed towards the sidewalls of the MRAM stacks 220a, 220b and re-deposited on the sidewalls. Some of the layers on the substrate 210, such as layers of the MTJ stack, may include metal atoms such as Fe, Co, and Ni atoms. As ion beam etching proceeds through the MTJ stack, such metal atoms may be dislodged and re-deposited on the sidewalls of the MRAM stacks 220a, 220b. When a conductive material is re-deposited on sidewalls of the tunnel barrier layer, which may be only a few nanometers thick, the magnetic layers are shorted in the MRAM stacks 220a, 220b.

The ion beam 225 applied to the substrate 210 may be directed at an angle. An angle of incidence of the ion beam 225 may be adjusted to control parameters such as etch rates, uniformity, shapes, topography, and composition of target surfaces. In some instances, the angle of incidence of the ion beam 225 is adjusted to clean sidewalls of re-deposited materials. A lower angle of incidence (i.e., more vertical) of the ion beam 225 can lead to more re-deposition of materials, whereas an optimized higher angle of incidence (i.e., less vertical) of the ion beam 225 can lead to cleaner sidewall surfaces by removing re-deposited materials. Furthermore, as device density increases and aspect ratios increase, an ion impact angle can become more shallow (ions strike the feature sidewall surface at a glancing angle). Higher device densities and aspect ratios limit the feasibility of using higher incident angles in cleaning sidewall surfaces. At the same time, the ion impact angle to a bottom layer becomes steeper, which causes poor bottom layer selectivity.

### Ion Beam Etching Apparatus

The present disclosure relates to ion beam etching of materials, where ion beam etching may be accompanied by gas treatment to limit re-deposition of sputtered atoms, molecules, or other etched byproducts. The gas treatment involves delivery of a reactive gas directly into a processing chamber where a substrate is positioned. In some implementations, the reactive gas includes a fluorine-containing gas such as sulfur hexafluoride (SF₆), carbon tetrafluoride (CF₄), or trifluoromethane (CHF₃), a nitrogen-containing gas such as ammonia (NH₃), a carbon-containing gas having a hydroxyl group such as methanol (CH₃OH), or mixtures thereof. In some implementations, the reactive gas is a carbon-containing gas having a hydroxyl group. The reactive gas is not ionized or radicalized. Delivery of the reactive gas to the processing chamber may be pulsed or continuous, and delivery of an ion beam from an ion beam source chamber to the processing chamber may be pulsed or continuous. In some implementations, delivery of the reactive gas may occur throughout an etch process or may occur at a beginning, middle, or end of the etch process. In some implementations, the present disclosure relates to pulsing an ion beam to etch one or more layers of an MRAM stack.

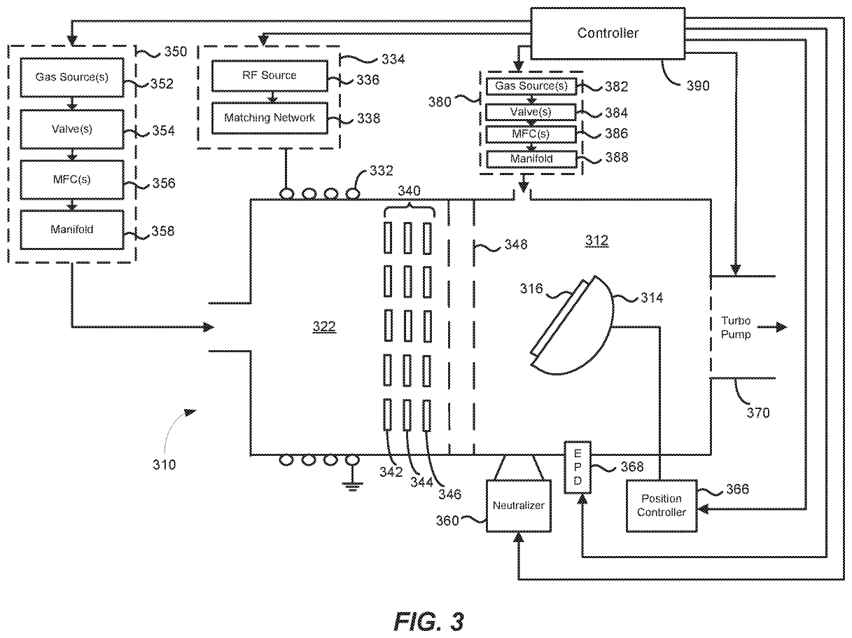

FIG. 3 is a schematic diagram of an example ion beam etching apparatus according to some implementations. An ion beam etching apparatus 310 includes a processing chamber 312 with a substrate holder 314 for supporting a substrate 316. The substrate 316 may be a semiconductor wafer. One or more MRAM stacks as described earlier may be formed on the substrate 316. Each MRAM stack may include an MTJ stack having one or more magnetic layers and a tunnel barrier layer. The substrate 316 may be attached to the substrate holder 314 using any suitable technique. For example, the substrate 316 is mechanically or electrostatically connected to the substrate holder 314. In some implementations, the substrate holder 314 provides precise tilting and rotation and may include an electrostatic chuck (ESC) to engage the substrate 316.

The ion beam etching apparatus 310 further includes an ion beam source chamber 322, where the processing chamber 312 may be outside of and coupled to the ion beam source chamber 322. The ion beam source chamber 322 may be separated from the processing chamber 312 by an ion extractor 340 and/or mechanical shutter 348. An inductive coil 332 may be arranged around an outer wall of the ion beam source chamber 322. A plasma generator 334 supplies RF power to the inductive coil 332. The plasma generator 334 may include an RF source 336 and a matching network 338. In use, a gas mixture is introduced to the ion beam source chamber 322 and RF power is supplied to the inductive coil 332 to generate plasma in the ion beam source chamber 322, where the plasma produces ions.

The ion beam etching apparatus 310 further includes a first gas delivery system 350 that is fluidly coupled to the ion beam source chamber 322. The first gas delivery system 350 delivers one or more gas mixtures to the ion beam source chamber 322. The first gas delivery system 350 may include one or more gas sources 352, valve(s) 354, mass flow controller(s) (MFCs) 356, and a mixing manifold 358 that are in fluid communication with the ion beam source chamber 322. In some implementations, the first gas delivery system 350 is configured to deliver an inert gas such as argon (Ar), xenon (Xe), or krypton (Kr). In some implementations, the first gas delivery system 350 delivers gas mixtures that are free or substantially free of reactive chemistries. As used herein, the term “substantially free” with respect to reactive chemistries in gas mixtures refers to an amount that is less than about 1% by volume with a balance of inert gas.

The ion extractor 340 extracts positive ions from the plasma and accelerates the positive ions in a beam towards the substrate 316. The ion extractor 340 may include a plurality of electrodes that form a grid or grid system. As shown in FIG. 3, the ion extractor 340 includes three electrodes, where a first electrode 342, a second electrode 344, and a third electrode 346 are present in that order from the first gas delivery system 350. A positive voltage is applied to the first electrode 342 and a negative voltage is applied to the second electrode 344 so that ions are accelerated due to a difference in their potentials. The third electrode 346 is grounded. A difference in potentials between the second electrode 344 and the third electrode 346 is controlled to control a diameter of an ion beam. In some implementations, application of DC voltage to the ion extractor 340 may be controlled to cause the ion beam to be delivered to continuously or in pulses.

A mechanical shutter 348 is adjacent to the ion extractor 340. A neutralizer 360 may supply electrons into the processing chamber 312 to neutralize the charge of the ion beam passing through the ion extractor 340 and the mechanical shutter 348, where the neutralizer 360 may have its own gas delivery system using an inert gas such as argon or xenon. In some implementations, the ion extractor 340 and/or mechanical shutter 348 may be controlled to cause the ion beam to be delivered to the substrate 316 continuously or in pulses.

A position controller 366 may be used to control a position of the substrate holder 314. In particular, the position controller 366 can control a tilt angle about a tilt axis and rotation of the substrate holder 314 to position the substrate 316. In some implementations, an endpoint detector 368 may be used to sense a location of the ion beam relative to the substrate 316 and/or substrate holder 314. A pump 370 such as a turbomolecular pump may be used to control pressure in the processing chamber 312 and evacuate reactants from the processing chamber 312.

In the present disclosure, the ion beam etching apparatus 310 further includes a second gas delivery system 380 fluidly coupled to the processing chamber 312. The second gas delivery system 380 delivers one or more gas mixtures directly into the processing chamber 312 without passing the gas mixtures through the ion beam source chamber 322. The second gas delivery system 380 may include one or more gas sources 382, valve(s) 384, mass flow controller(s) (MFCs) 386, and a mixing manifold 388 that are in fluid communication with the processing chamber 312. In some implementations, the second gas delivery system 380 is configured to deliver a reactive gas such as a carbon-containing gas having a hydroxyl group. For example, the carbon-containing gas is selected from a group consisting of: an alcohol, a carboxylic acid, an organic hydroperoxide, a hemiacetal, and a hemiketal. In some implementations, the carbon-containing gas includes methanol. In some implementations, the carbon-containing gas may be added with other gases including an inert gas such as argon, xenon, or krypton. The carbon-containing gas, or at least a substantial fraction of the carbon-containing gas, is not ionized or radicalized when provided to the substrate 316. The carbon-containing gas may be flowed into the processing chamber 312 continuously or in pulses. The carbon-containing gas may be flowed into the processing chamber 312 throughout an ion beam etching operation or at a beginning, middle, or end of the ion beam etching operation. In some implementations, the reactive gas delivered by the second gas delivery system 380 is a fluorine-containing gas such as sulfur hexafluoride, carbon tetrafluoride, or trifluoromethane instead of a carbon-containing gas. In some implementations, the reactive gas delivered by the second gas delivery system 380 is a nitrogen-containing gas such as ammonia. Fluorine-containing gas, nitrogen-containing gas, and carbon-containing gas may be delivered by the second gas delivery system 380 individually or in mixtures thereof.

The ion beam etching apparatus 310 may further include a controller 390. The controller 390 (which may include one or more physical or logical controllers) controls some or all of the operations of the ion beam etching apparatus 310. In some implementations, the controller 390 may be used to control the plasma generator 334, the first gas delivery system 350, the neutralizer 360, the position controller 366, the pump 370, and the second gas delivery system 380. The controller 390 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller 390 they may be provided over a network. In certain implementations, the controller 390 executes system control software. The system control software may include instructions for controlling the timing of application and/or magnitude of any one or more of the following chamber operational conditions: the mixture and/or composition of gases, flow rates of gases, chamber pressure, chamber temperature, substrate/substrate holder temperature, substrate position, substrate holder tilt, substrate holder rotation, voltage applied to a grid, the frequency and power applied to coils or other plasma generation components, and other parameters of a particular process performed by the tool. The system control software may further control purge operations and cleaning operations through the pump 370. System control software may be configured in any suitable way. For example, various process tool component subroutines or control objects may be written to control operations of the process tool components necessary to carry out various process tool processes. System control software may be coded in any suitable compute readable programming language.

In some implementations, system control software includes input/output control (IOC) sequencing instructions for controlling the various parameters described above. For example, each phase of a semiconductor fabrication process may include one or more instructions for execution by the controller 390. The instructions for setting process conditions for a phase may be included in a corresponding recipe phase, for example. In some implementations, the recipe phases may be sequentially arranged, such that steps in an ion beam etching process are executed in a certain order for that process phase. For example, a recipe may be configured to perform ion beam etch operations and include gas treatment with a reactive gas at certain time intervals.

In some implementations, the controller 390 is configured with instructions for performing one or more of the following operations: generate an ion beam of an inert gas in an ion beam source chamber 322, apply the ion beam of the inert gas to a substrate 316 in a processing chamber 312 outside the ion beam source chamber 322, where the ion beam etches one or more layers of an MRAM stack on a substrate, and introduce a reactive gas directly into the processing chamber 312 towards the substrate 316. The one or more layers of the MRAM stack may include one or more magnetic layers. The reactive gas may include a carbon-containing gas having a hydroxyl group.

Other computer software and/or programs may be employed in some implementations. Examples of programs or sections of programs for this purpose include substrate positioning program, a process gas composition control program, a pressure control program, a heater control program, and an RF power supply control program.

The controller 390 may control these and other aspects based on sensor output (e.g., when power, potential, pressure, gas levels, etc. reach a certain threshold), the timing of an operation (e.g., opening valves at certain times in a process, pulsing ion beam delivery, pulsing gas treatment delivery, etc.), or based on received instructions from the user.

Broadly speaking, the controller 390 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 390 in the form of various individual settings (or program files), defining operational parameters for carrying out a particular process on or for a semiconductor substrate or to a system. The operational parameters may, in some implementations, be part of a recipe defined by process engineers to accomplish one or more processing steps during the patterning of MRAM stacks on a substrate.

The controller 390, in some implementations, may be a part of or coupled to a computer that is integrated with, coupled to the system, otherwise networked to the system, or a combination thereof. For example, the controller 390 may be in the “cloud” or all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 390 receives instructions in the form of data, which specify parameters for each of the processing steps to be performed during one or more operations. It should be understood that the parameters may be specific to the type of process to be performed and the type of tool that the controller 390 is configured to interface with or control. Thus as described above, the controller 390 may be distributed, such as by comprising one or more discrete controllers that are networked together and working towards a common purpose, such as the processes and controls described herein. An example of a distributed controller 390 for such purposes would be one or more integrated circuits on a chamber in communication with one or more integrated circuits located remotely (such as at the platform level or as part of a remote computer) that combine to control a process on the chamber.

As noted above, depending on the process step or steps to be performed by the tool, the controller 390 might communicate with one or more of other tool circuits or modules, other tool components, cluster tools, other tool interfaces, adjacent tools, neighboring tools, tools located throughout a factory, a main computer, another controller 390, or tools used in material transport that bring containers of substrates to and from tool locations and/or load ports in a semiconductor manufacturing factory.

Ion Beam Etching with Gas Treatment and/or Pulsing

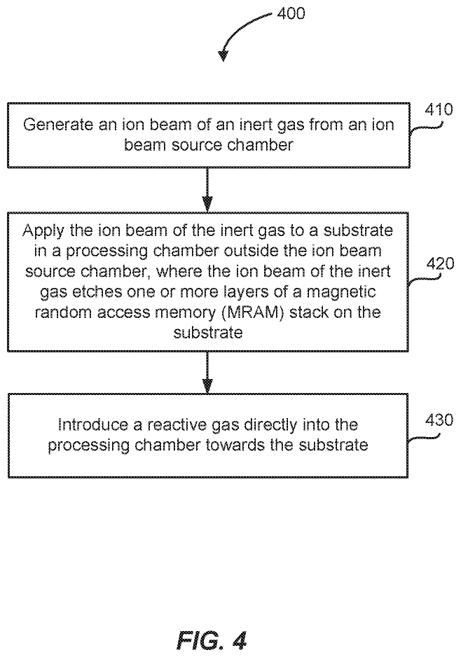

FIG. 4 shows a flow diagram of an example method of ion beam etching a substrate according to some implementations. Operations of a process 400 in FIG. 4 may include additional, fewer, or different operations.

At block 410 of the process 400, an ion beam of an inert gas is generated from an ion beam source chamber. A gas mixture including an inert gas is introduced into ion beam source chamber. The inert gas can include argon, xenon, krypton, or combinations thereof. The gas mixture can be free or substantially free of reactive gas. RF power is applied to coils outside of the ion beam source chamber to generate plasma in the ion beam source chamber. In some implementations, the ion beam source chamber may also be referred to as a plasma generating chamber or plasma chamber. Ions are extracted from the plasma to form an ion beam. In some implementations, a voltage is applied to an ion extractor (e.g., grid) to extract ions to form the ion beam of the inert gas from the ion beam source chamber. After ions are extracted from the plasma, the ion beam may be accelerated towards a processing chamber, where the processing chamber is separated from the ion beam source chamber by the ion extractor and/or a mechanical shutter.

At block 420 of the process 400, the ion beam of the inert gas is applied to a substrate in the processing chamber outside the ion beam source chamber. The ion beam of the inert gas etches one or more layers of a magnetic random access memory (MRAM) stack on the substrate. In some implementations, the one or more layers of the MRAM stack being etched include one or more magnetic layers of a magnetic tunnel junction (MTJ) stack. The MTJ stack may include a top magnetic layer, a bottom magnetic layer, and a barrier layer between the top magnetic layer and the bottom magnetic layer. In some implementations, the barrier layer includes a non-magnetic insulating material (e.g., MgO). In some implementations, the one or more layers of the MRAM stack being etched includes one or more silicon-containing layers, one or more layers of dielectric materials such as silicon dioxide, and/or one or more layers of hard mask materials such as tungsten.

In some implementations, the ion beam of the inert gas is an Ar⁺ ion beam directed into the processing chamber. The ion beam of the inert gas may be directed from the ion beam source chamber to the processing chamber in pulses or continuously. In some implementations, the ion beam of the inert gas is directed to the processing chamber continuously. In some implementations, the ion beam of the inert gas is directed to the processing chamber in pulses. By way of an example, a grid and/or a mechanical shutter may be positioned between two states, though it will be understood that the grid and/or mechanical shutter may be positioned in more than two states. In a first state, no ions will be able to pass through to the processing chamber. In a second state, some or all of the ions will be able to pass through the processing chamber. Ion beam pulsing may be achieved by alternating between the first and the second state. By way of another example, RF power supplied to ion beam source chamber for generating a plasma may be supplied in pulses, thereby providing a pulsed plasma waveform. As a result, ion beam pulsing may be achieved from a pulsed plasma waveform. By way of another example, the gas mixture including the inert gas may be supplied in pulses into the ion beam source chamber. By way of another example, DC input provided to the grid of an ion extractor may be applied in pulses. Consequently, extraction of ions for generating an ion beam from plasma may occur in pulses. By way of another example, an ion beam may be pulsed between ion beams of different densities (e.g., alternating between a high ion beam density and a low ion beam density) by controlling electromagnetic (EM) current applied to the ion beam source chamber during plasma generation. Specifically, a first state may apply a first magnetic field to cause a first spatial distribution of plasma and a second state may apply a second magnetic field to cause a second spatial distribution of plasma, thereby changing ion beam density between the two states. Thus, as described above, ion beam pulsing may occur using one or more of the following techniques: (1) alternating the grid/mechanical shutter between open and closed states, (2) pulsing the RF input on the coil during plasma generation, (3) pulsing the gas input into the ion beam source chamber, (4) pulsing the DC input on the grid of the ion extractor, and (5) pulsing the EM current applied to the ion beam source chamber to vary ion beam density.

In some implementations, ion beam pulsing may occur across multiple values and is not limited to alternating between an ON state where an ion beam is provided and an OFF state where no ion beam is provided. In other words, a characteristic of an ion beam such as its density may be modulated over time. This allows ion beam pulsing to modulate across different values. For example, by modulating the DC input on the grid of the ion extractor, more or less ions may be extracted over time instead of alternating between no ions extracted and some ions extracted. Thus, ion beam pulsing may be provided more as a staircase of values or other series of values instead of provided as a square waveform between 0 and 1.

The ion beam of the inert gas is applied to the substrate to etch one or more layers of a thin film stack on the substrate. In some implementations, the ion beam of the inert gas is applied to the substrate to etch a hard mask layer and a dielectric layer of an MRAM stack. In some implementations, the ion beam of the inert gas is applied to the substrate to etch a top magnetic layer, a bottom magnetic layer, and a barrier layer of an MTJ stack formed on the substrate. Typically, in etching the one or more magnetic layers, etch byproducts are produced that may be re-deposited on exposed surfaces of the substrate. The etched byproducts may include metal-containing atoms or molecules. These etch byproducts may include sputtered atoms and molecules etched from the one or more magnetic layers when the ion beam is applied to the one or more magnetic layers. The one or more magnetic layers may include non-volatile materials, where the non-volatile materials may include magnetic materials such as Fe, Co, Ni, and the like. When the etch byproducts are re-deposited on exposed surfaces, including on the exposed sidewall surfaces of the barrier layer, the MTJ stack is compromised and can lead to shorting.

In some implementations, the ion beam of the inert gas is applied to the substrate at an angle. The angle of incidence of the ion beam relative to the substrate surface may be controlled by tilting or rotating a substrate holder for supporting the substrate.

At block 430 of the process 400, a reactive gas is introduced directly into the processing chamber towards the substrate. In some implementations, the reactive gas includes a carbon-containing gas having a hydroxyl group. The carbon-containing gas is selected from a group consisting of: an alcohol, a carboxylic acid, an organic hydroperoxide (R—O—OH), a hemiacetal (RCH(OR′)(OH)), and a hemiketal (RC(OR″)(OH)R′). Examples of alcohols include but are not limited to methanol, ethanol, propanol, isopropyl alcohol, and butanol. Examples of carboxylic acids include but are not limited to carbonic acid, formic acid, acetic acid, propionic acid, and butyric acid. It will be appreciated that a combination of the aforementioned gases or other gases in addition to the carbon-containing gas may be introduced directly into the processing chamber.

In some implementations, the reactive gas includes a fluorine-containing gas such as sulfur hexafluoride, carbon tetrafluoride, or trifluoromethane. In some implementations, the reactive gas includes a nitrogen-containing gas such as ammonia. Such reactive gases may be introduced directly into the processing chamber towards the substrate in lieu of the carbon-containing gas having the hydroxyl group or in addition to the carbon-containing gas having the hydroxyl group.

The reactive gas is introduced into the processing chamber without passing through the ion beam source chamber. The reactive gas is introduced downstream from the ion beam source chamber. Plasma of the reactive gas is not generated. Thus, radicals and ions of the reactive gas are generally not formed upon introduction into the processing chamber. Furthermore, dissociation of the reactive gas is avoided or minimized. Without being limited by any theory, the effect of the hydroxyl group (—OH) can be maximized when the carbon-containing gas is not dissociated. This can minimize chemical reactions of the carbon-containing gas with materials and layers of the MRAM stack when the carbon-containing gas is not dissociated. In addition, the ion beam of the inert gas can be energized towards the substrate so that a mean free path of the ions avoids or minimizes dissociation of the reactive gas. In some implementations, a free mean path of the ions from the ion beam is equal to or greater than about 20 cm, equal to or greater than about 25 cm, or equal to or greater than about 30 cm. The reactive gas, or at least a substantial fraction of the reactive gas, is not ionized or radicalized in an environment adjacent to the substrate. As used herein, “a substantial fraction” of the reactive gas can refer to values equal to or greater than about 95% of a total concentration of the reactive gas.

Without being limited by any theory, it is hypothesized that the reactive gas, such as the carbon-containing gas having a hydroxyl group, serves to passivate the sidewalls of the MRAM stack and/or react with non-volatile materials from the MRAM stack to make them volatile for removal instead of re-deposition. If the reactive gas is passivating the sidewalls of the MRAM stack, the bonds of the reactive gas may function to passivate the sidewalls so that etched byproducts do not stick to the sidewalls. That way, sputtered atoms or molecules from ion beam etching are not re-deposited on the sidewalls of the MRAM stack. In addition or in the alternative, if the reactive gas is able to make non-volatile materials such as the etched byproducts become volatile materials, then the reactive gas may function to remove re-deposited materials from sidewalls or prevent re-deposition from happening in the first place. Regardless of the hypothesized mechanism, introduction of the carbon-containing gas directly into the processing chamber can result in cleaner sidewalls of the MRAM stack.

Sidewalls of the MRAM stack after introduction of the reactive gas may be free or substantially free of re-deposited etched byproducts. As used herein, “substantially free” with respect to re-deposited etched byproducts on sidewalls of the MRAM stack refers to a total surface area on sidewalls of the MRAM stack that is covered less than about 5% with re-deposited etched byproducts.

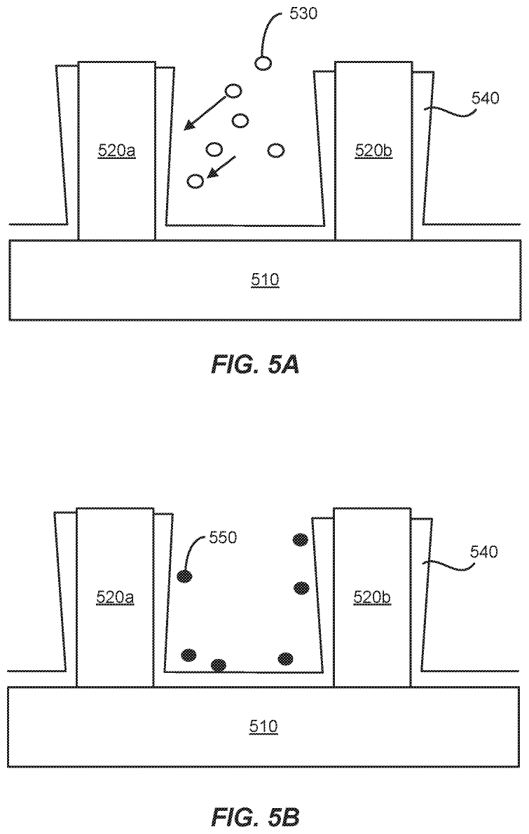

FIGS. 5A-5B show cross-sectional schematic illustrations of carbon-containing gas passivating sidewalls and exposed surfaces of MRAM stacks to limit sidewall re-deposition. In FIG. 5A, MRAM stacks 520a, 520b are formed on a substrate 510. The MRAM stacks 520a, 520b include one or more magnetic layers. In some implementations, each of the MRAM stacks 520a, 520b includes a MTJ stack, where the MTJ stack includes a top magnetic layer, a bottom magnetic layer, and a barrier layer (e.g., MgO) between the top magnetic layer and the bottom magnetic layer. Carbon-containing gas 530 having a hydroxyl group (—OH) is introduced and adsorbed onto surfaces of the substrate 510 and on sidewalls of the MRAM stacks 520a, 520b. In some implementations, the carbon-containing gas is methanol. The carbon-containing gas 530 may passivate exposed surfaces of the substrate 510 and sidewalls of the MRAM stacks 520a, 520b. As shown in FIGS. 5A-5B, the carbon-containing gas 530 may form a passivation layer 540 on exposed surfaces of the substrate 510 and sidewalls of the MRAM stacks 520a, 520b. In FIG. 5B, when the substrate 510 and the MRAM stacks 520a, 520b are exposed to an ion beam of an inert gas, sputtered atoms and/or molecules 550 may be prevented from re-depositing because of the passivation layer 540 on sidewalls and surfaces.

Returning to FIG. 4 of the process 400, the reactive gas may be introduced into the processing chamber when performing ion beam etching. In some implementations, a pressure of the reactive gas in the processing chamber is between about 0.05 mTorr and about 1 mTorr, between about 0.1 mTorr and about 0.6 mTorr, or between about 0.2 mTorr and about 0.5 mTorr. Otherwise, a base pressure in the processing chamber without the reactive gas is equal to or less than about 1 mTorr, or between about 0.1 mTorr and about 1 mTorr.

As discussed above, the ion beam of the inert gas may be applied to the substrate to etch one or more layers of an MRAM stack on the substrate. The voltage applied to generate the ion beam may vary when performing ion beam etching. In some implementations, the voltage applied to an ion extractor for extracting ions and generating an ion beam may vary to control an etch rate when performing ion beam etching. The applied voltage may control the acceleration of ions towards the substrate surface. In some implementations, a low voltage ion beam may be applied to perform a less aggressive etch or “soft etch,” where the applied voltage may be between about 30 V and about 200 V for a low voltage ion beam. In some implementations, a high voltage ion beam may be applied to perform a more aggressive etch or “fast etch,” where the applied voltage may be between about 400 V and about 2000 V for a high voltage ion beam. The applied voltage may change depending on whether a reactive gas is being flowed to the substrate or not. For example, the low voltage ion beam may be applied when simultaneously flowing the reactive gas into the processing chamber, thereby promoting surface passivation and limiting re-deposition. The high voltage ion beam may be applied when no reactive gas is being flowed into the processing chamber, thereby promoting etching of layers and materials disposed on the substrate.

The reactive gas, such as a carbon-containing gas having a hydroxyl group, may be flowed simultaneously with the ion beam or may be flowed in separate iterations from the ion beam. In some implementations, the flow of the reactive gas into the processing chamber may be pulsed or continuous. In some implementations, application of the ion beam from the ion beam source chamber to the processing chamber may be pulsed or continuous. Controlling the timing of delivery of the reactive gas with the timing of delivery of the ion beam may influence an amount of re-deposition of etched byproducts as well as the electrical and magnetic properties of an MRAM stack.

In some implementations, the flow of the reactive gas is continuous while the application of the ion beam is continuous. For example, the ion beam may be generated from a continuous wave plasma. Thus, in-situ ion beam etching can occur with continuous reactive gas flow.

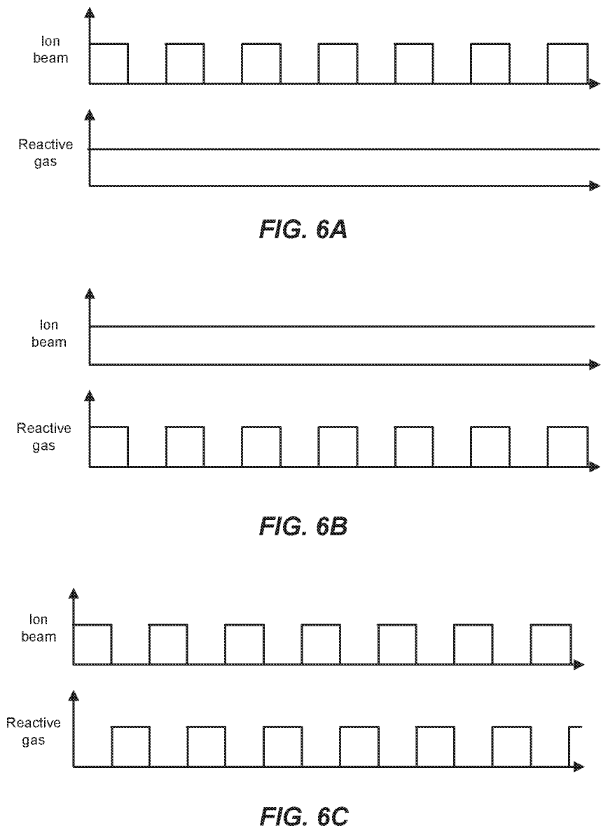

In some implementations, the flow of the reactive gas is continuous while the application of the ion beam is pulsed. FIG. 6A shows a timing diagram of applying an ion beam in pulses simultaneous with flowing continuously reactive gas according to some implementations. For example, the ion beam may be generated from a pulsed plasma waveform, from controlling open/closed states in a grid/shutter of an ion extractor, from introducing inert gas in pulses, from applying DC input in pulses, or from modulating EM current provided in plasma generation. In some implementations, a pulsing frequency of the ion beam is between about 0.05 Hz and about 5 kHz, or between about 0.1 Hz and about 1 kHz. Delivery of the ion beam in pulses may limit the amount of etched byproducts from ion beam etching and potentially limit the re-deposition of such etched byproducts. In addition, delivery of the ion beam in pulses may limit damage to the electrical and magnetic properties of the MRAM stack.

In some implementations, the flow of the reactive gas is pulsed while the application of the ion beam is continuous. FIG. 6B shows a timing diagram of applying an ion beam continuously simultaneous with pulsing reactive gas according to some implementations. The flow of the reactive gas may be turned on and turned off to control delivery of the reactive gas into the processing chamber. This may control an amount of exposure of the substrate to the reactive gas. In some implementations, a pulsing frequency of the reactive gas is between about 0.05 Hz and about 5 kHz, or between about 0.1 Hz and about 1 kHz. Without being limited by any theory, a continuous flow of reactive gas may lead to an excess amount of reactive gas that can react with materials in the MRAM stack that can compromise its electrical and magnetic properties. In other words, too much reactive gas can potentially degrade the TMR effect in the MRAM stack, thereby adversely impacting the performance of MRAM cells. Pulsing the reactive gas may limit re-deposition of unwanted materials while largely preserving the electrical and magnetic properties of the MRAM stack. In some implementations, flow of reactive gas may be provided with application of a low voltage ion beam to promote surface passivation and limit re-deposition, and flow of reactive gas may be stopped with application of a high voltage ion beam to promote etching.

In some implementations, the flow of the reactive gas is pulsed while the application of the ion beam is pulsed. In one example, the reactive gas may be pulsed in a manner that is synchronized with the ion beam. In another example, the reactive gas is pulsed in a manner that is alternating with the pulses of the ion beam. FIG. 6C shows a timing diagram of applying an ion beam in pulses that alternates with pulsing reactive gas according to some implementations. Accordingly, the MRAM stack on the substrate will undergo operations of surface passivation during exposure to the reactive gas that alternates with ion beam etching during exposure to the ion beam.

Aspects of pulsing the reactive gas or the ion beam may involve modulating features such as pulsing frequency, duty cycle, and amplitude. In some implementations, one or both of a pulsing frequency of the reactive gas and a pulsing frequency of an ion beam is between about 0.05 Hz and about 5 kHz, or between about 0.1 Hz and about 1 kHz. In some implementations, one or both of a duty cycle of the reactive gas and a duty cycle of an ion beam is between about 0% and about 100%. Values of pulsing frequency, duty cycle, and amplitude may be modulated over time when pulsing the reactive gas or when pulsing the ion beam. For example, the amplitude of the ion beam may be modulated over time when pulsing the ion beam. Rather than a square waveform as shown in FIGS. 6A and 6C, the ion beam may be pulsed with a stepped waveform or type of waveform of modulating values.

In some implementations, the reactive gas may be provided at a segment of time that occurs at the beginning, middle, or end of the ion beam etching operation. Delivery of the reactive may occur at the segment of time that is optimal for limiting re-deposition of etched byproducts and limiting damage to the electrical and magnetic properties of the MRAM stack. Timing of delivery of the reactive gas may be controlled to promote surface passivation and ion beam etching. In some implementations, the flow of the reactive gas may be continuous or pulsed at the beginning, middle, or end of the ion beam etching operation. Application of the ion beam during the ion beam etching operation may be pulsed or continuous.

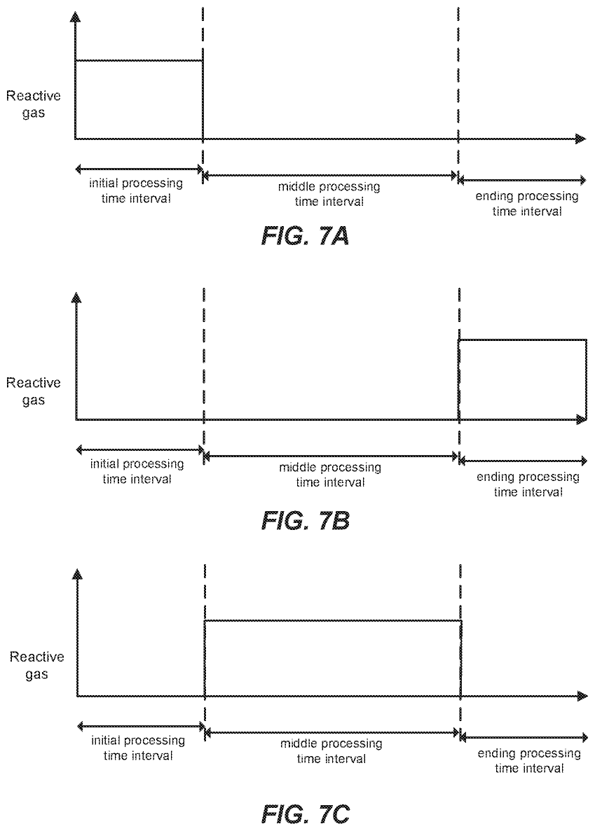

In some implementations, the reactive gas is flowed into the processing chamber during an initial processing time interval when etching the one or more layers of the MRAM stack. FIG. 7A shows a timing diagram of flowing reactive gas at an initial processing time interval when performing ion beam etching according to some implementations. Ion beam etching of the MRAM stack may occur over a total processing time for etching at least the one or more layers of the MRAM stack. The total processing time can be broken up into: (1) an initial processing time interval, (2) a middle processing time interval, and (3) an ending processing time interval. In FIG. 7A, the flow of reactive gas is turned on during the initial processing time interval and then turned off for a remainder of time for ion beam etching. In some implementations, the initial processing time interval can represent a segment of time during ion beam etching that occurs at the onset of the ion beam etching. In some implementations, the initial processing time interval can be a segment of time that is at least 5%, at least 10%, at least 20%, at least 30%, between about 5% and about 50%, between about 10% and about 40%, or between about 15% and about 35% of the total processing time of ion beam etching. For example, if the total processing time were 20 minutes, then the initial processing time interval can represent the first 5 minutes of the total processing time.

In some implementations, the reactive gas is flowed into the processing chamber during an ending processing time interval when etching the one or more layers of the MRAM stack. FIG. 7B shows a timing diagram of flowing reactive gas at an ending processing time interval when performing ion beam etching according to some implementations. In FIG. 7B, the flow of reactive gas is turned off during the initial processing time interval and then the flow of reactive gas is turned on for a remainder of time for ion beam etching. In some implementations, the ending processing time interval can represent a segment of time during ion beam etching that occurs after (and not at) the onset of ion beam etching. In some implementations, the ending processing time interval can be a segment of time that is at least 5%, at least 10%, at least 20%, at least 30%, between about 5% and about 50%, between about 10% and about 40%, or between about 15% and about 35% of the total processing time of ion beam etching. By way of an example, if the total processing time were 20 minutes, then the ending processing time interval can represent the last 5 minutes of the total processing time.

In some implementations, the reactive gas is flowed into the processing chamber during a middle processing time interval when etching the one or more layers of the MRAM stack. FIG. 7C shows a timing diagram of flowing reactive gas at a middle processing time interval when performing ion beam etching according to some implementations. In FIG. 7C, the flow of reactive gas is turned off during the initial processing time interval, flowed into the processing chamber during the middle processing time interval, and the flow of the reactive gas is turned off thereafter. In some implementations, the middle processing time interval can represent a segment of time during ion beam etching that occurs after the beginning but before the end of ion beam etching. In some implementations, the middle processing time interval can be a segment of time that is at least 5%, at least 10%, at least 20%, at least 30%, between about 5% and about 95%, between about 10% and about 80%, or between about 15% and about 50% of the total processing time of ion beam etching. By way of an example, if the total processing time were 20 minutes, then the middle processing time interval can represent a 5-minute span that occurs anywhere between a beginning (t₁=0 minutes) and end (t₂=20 minutes) of the total processing time.

### CONCLUSION

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of ion beam etching a substrate, the method comprising:
generating an ion beam of an inert gas from an ion beam source chamber;
applying the ion beam of the inert gas to a substrate in a processing chamber outside the ion beam source chamber, wherein the ion beam etches one or more layers of a magnetic random access memory (MRAM) stack on the substrate; and
introducing a reactive gas directly into the processing chamber and towards the substrate.

2. The method of claim 1, wherein the reactive gas includes a carbon-containing gas having a hydroxyl group.

3. The method of claim 2, wherein the carbon-containing gas is selected from a group consisting of: an alcohol, a carboxylic acid, an organic hydroperoxide, a hemiacetal, and a hemiketal.

4. The method of claim 3, wherein the carbon-containing gas includes methanol.

5. The method of claim 1, wherein the reactive gas includes a fluorine-containing gas or a nitrogen-containing gas.

6. The method of claim 1, wherein the MRAM stack includes an MTJ stack, wherein the MTJ stack includes a top magnetic layer, a bottom magnetic layer, and a tunnel barrier layer between the top magnetic layer and the bottom magnetic layer.

7. The method of claim 1, wherein sidewalls of the MRAM stack after etching the one or more layers and after introducing the reactive gas are substantially free of re-deposited etched byproducts.

8. The method of claim 1, wherein applying the ion beam comprises applying the ion beam continuously to etch the one or more layers of the MRAM stack.

9. The method of claim 8, wherein introducing the reactive gas occurs simultaneously with applying the ion beam, wherein introducing the reactive gas comprises continuously flowing the reactive gas directly into the processing chamber.

10. The method of claim 8, wherein introducing the reactive gas occurs simultaneously with applying the ion beam, wherein introducing the reactive gas comprises pulsing the reactive gas directly into the processing chamber.

11. The method of claim 1, wherein applying the ion beam comprises pulsing the ion beam to etch the one or more layers of the MRAM stack.

12. The method of claim 11, wherein introducing the reactive gas occurs simultaneously with applying the ion beam, wherein introducing the reactive gas comprises continuously flowing the reactive gas directly into the processing chamber.

13. The method of claim 11, wherein introducing the reactive gas comprises pulsing the reactive gas directly into the processing chamber.

14. The method of claim 11, wherein an amplitude of the ion beam is modulated over time when pulsing the ion beam.

15. The method of claim 1, wherein introducing the reactive gas comprises flowing the reactive gas during an initial processing time interval when etching the one or more layers of the MRAM stack.

16. The method of claim 1, wherein introducing the reactive gas comprises flowing the reactive gas during an ending processing time interval when etching the one or more layers of the MRAM stack.

17. The method of claim 1, wherein introducing the reactive gas comprises flowing the reactive gas during a middle processing time interval when etching the one or more layers of the MRAM stack.

18. The method of claim 1, wherein a pressure of the reactive gas in the processing chamber is between about 0.1 mTorr and about 0.6 mTorr.

19. A method of ion beam etching a substrate, the method comprising:
generating an ion beam of an inert gas in an ion beam source chamber; and
pulsing the ion beam of the inert gas to a substrate in a processing chamber outside the ion beam source chamber, wherein the ion beam etches one or more layers of a magnetic random access memory (MRAM) stack on the substrate.

20. The method of claim 19, wherein an amplitude of the ion beam is modulated over time when pulsing the ion beam.

21. The method of claim 19, further comprising:
introducing a reactive gas directly into the processing chamber towards the substrate.

22. The method of claim 21, wherein the reactive gas includes a carbon-containing gas having a hydroxyl group, wherein the carbon-containing gas is selected from a group consisting of: an alcohol, a carboxylic acid, an organic hydroperoxide, a hemiacetal, and a hemiketal.

23. The method of claim 21, wherein the reactive gas is flowed continuously.

24. The method of claim 21, wherein the reactive gas is pulsed.

25. The method of claim 24, wherein the ion beam of the inert gas and the reactive gas are alternatingly pulsed into the processing chamber.

26. The method of claim 21, wherein the reactive gas is flowed during an initial processing time interval when etching the one or more layers of the MRAM stack.

27. The method of claim 21, wherein the reactive gas is flowed during an ending processing time interval when etching the one or more layers of the MRAM stack.

28. The method of claim 21, wherein the reactive gas is flowed during a middle processing time interval when etching the one or more layers of the MRAM stack.

29. An apparatus for performing ion beam etching of a substrate, the apparatus comprising:
an ion beam source chamber;
a processing chamber coupled to the ion beam source chamber, wherein the processing chamber is configured to support a substrate located therein, wherein a magnetic random access memory (MRAM) stack includes one or more layers disposed on the substrate;
a gas delivery system coupled to the processing chamber; and
a controller configured to provide instructions to perform the following operations:
generate an ion beam of an inert gas in the ion beam source chamber;
apply the ion beam of the inert gas to the substrate in the processing chamber, wherein the ion beam etches the one or more layers of the MRAM stack on the substrate; and
introduce a reactive gas through the gas delivery system and directly into the processing chamber towards the substrate.

30.-36. (canceled)
